(19) United States
(12) Patent Application Publication
(10) Pub. No.: US 2013/0112264 A1
(43) Pub. Date: May 9, 2013

(54) METHODS FOR FORMING A DOPED AMORPHOUS SILICON OXIDE LAYER FOR SOLAR CELL DEVICES

(71) Applicants: Dapeng Wang, Santa Clara, CA (US); Yong Kee Chae, San Ramon, CA (US)

(72) Inventors: Dapeng Wang, Santa Clara, CA (US); Yong Kee Chae, San Ramon, CA (US)

(73) Assignee: APPLIED MATERIALS, INC., Santa Clara, CA (US)

(21) Appl. No.: 13/291,288

(22) Filed: Nov. 8, 2011

(51) Int. Cl. H01L 31/0376; H01L 21/20

(52) U.S. Cl. 136/258; 438/483; 438/93; 438/96; 257/E21.09; 257/E31.047

(57) ABSTRACT

Embodiments of the present invention relate to methods for forming a doped amorphous silicon oxide layer utilized in thin film solar cells. In one embodiment, a method for forming a doped p-type amorphous silicon containing layer on a substrate includes providing a substrate in a processing chamber, supplying a gas mixture having a hydrogen-based gas, a silicon-based gas and a carbon and oxygen containing gas into the processing chamber, the gas mixture having a volumetric flow ratio of the hydrogen-based gas to the silicon-based gas between about 5 and about 15, wherein a volumetric flow ratio of the carbon and oxygen containing gas to the total combined flow of hydrogen-based gas and the silicon-based gas is between about 10 percent and about 50 percent; and maintaining a process pressure of the gas mixture within the processing chamber at between about 1 Torr and about 10 Torr while forming a doped p-type amorphous silicon containing layer.

### BACKGROUND OF THE INVENTION

1. Field of the Invention

Embodiments of the present invention generally relate to solar cells and methods and apparatuses for forming the same. More particularly, embodiments of the present invention relate to methods and apparatus for forming a doped amorphous silicon oxide layer that may be utilized in thin film single or multiple junction solar cells.

2. Description of the Related Art

Solar cells convert solar radiation and other light into usable electrical energy. The energy conversion occurs as the result of the photovoltaic effect. Solar cells may be formed from crystalline material or from amorphous or micro-crystalline materials. Generally, there are two major types of solar cells that are produced in large quantities today, which are crystalline silicon solar cells and thin film solar cells. Crystalline silicon solar cells typically use either mono-crystalline substrates (i.e., single-crystal substrates of pure silicon) or a multi-crystalline silicon substrates (i.e., poly-crystalline or polysilicon). Additional film layers are deposited onto the silicon substrates to improve light capture, form the electrical circuits, and protect the devices. Thin-film solar cells use thin layers of materials deposited on suitable substrates to form one or more p-n junctions. Suitable substrates include glass, metal, and polymer substrates. It has been found that the properties of thin-film solar cells degrade over time upon exposure to light, which can cause the device stability to be less than desired. Typical solar cell properties that may degrade are the fill factor (FF), short circuit current, and open circuit voltage (Voc).

Problems with current thin film solar cells include low efficiency and high cost. Therefore, there is a need for improved thin film solar cells and methods and apparatuses for forming the same in a factory environment. There is also a need for a process which will fabricate high stability p-i-n solar cells having high fill factor, high short circuit current, high open circuit voltage and good device stability.

### SUMMARY OF THE INVENTION

Embodiments of the present invention relate to methods for forming a doped amorphous silicon oxide layer utilized in thin film solar cells. In one embodiment, a method for forming a doped p-type amorphous silicon containing layer on a substrate includes transferring a substrate into a processing chamber, supplying a gas mixture having a hydrogen-based gas, a silicon-based gas and a carbon and oxygen containing gas into the processing chamber, the gas mixture having a volumetric flow ratio of the hydrogen-based gas to the silicon-based gas between about 5 and about 15, wherein a volumetric flow ratio of the carbon and oxygen containing gas to the total combined flow of hydrogen-based gas and the silicon-based gas is between about 10 percent and about 50 percent, and maintaining a process pressure of the gas mixture within the processing chamber at between about 1 Torr and about 10 Torr while forming a doped p-type amorphous silicon containing layer.

In another embodiment, a method for forming a doped p-type amorphous silicon containing layer on a substrate for solar cell devices includes transferring a substrate having a fluorine doped tin oxide layer disposed thereon into a processing chamber, supplying a gas mixture having a H₂ gas, a SiH₄ gas and an CO₂ gas into the processing chamber, wherein the H₂ gas to SiH₄ gas having a volumetric flow ratio of between about 5 and about 15, wherein volumetric flow ratio of the CO₂ gas to the total combined flow of H₂ gas and the SiH₄ gas is between about 10 percent and about 50 percent, and applying a RF power to form a plasma in the presence of the gas mixture to deposit a carbon doped p-type amorphous silicon oxide layer on the substrate, wherein the carbon doped p-type amorphous silicon oxide layer is controlled to have a carbon concentration between about 0.1 atomic percent and about 10 atomic percent.

In yet another embodiment, a thin film solar cell structure includes a first transparent conductive oxide layer disposed on a substrate, a carbon doped p-type amorphous silicon oxide layer disposed on the first transparent conductive layer, wherein the carbon concentration doped in the carbon doped p-type amorphous silicon oxide layer is between about 0.1 atomic percent and about 10 atomic percent, an intrinsic type silicon containing layer disposed on the carbon doped p-type amorphous silicon oxide layer, and a n-type silicon containing layer disposed on the carbon doped p-type amorphous silicon oxide layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1 depicts a schematic diagram of one embodiment of a thin film solar cell device oriented toward the light or solar radiation.

FIG. 2 depicts a schematic cross-section view of one embodiment of a plasma enhanced chemical vapor deposition (PECVD) chamber in which one or more films of a solar cell may be deposited;

FIG. 3 depicts a top schematic view of one embodiment of a process system having a plurality of process chambers;

FIG. 4 depicts a flow diagram of a method for forming a doped amorphous silicon oxide layer utilized in thin film solar cell devices according to one embodiment of the invention; and

FIGS. 5A-5B depict a sequence for forming a doped amorphous silicon oxide layer on a substrate according to one embodiment of the invention.

It is to be noted, however, that the appended drawings illustrate only typical embodiments of this invention and are therefore not to be considered limiting of its scope, for the invention may admit to other equally effective embodiments.

To facilitate understanding, identical reference numerals have been used, where possible, to designate identical elements that are common to the figures.

### DETAILED DESCRIPTION

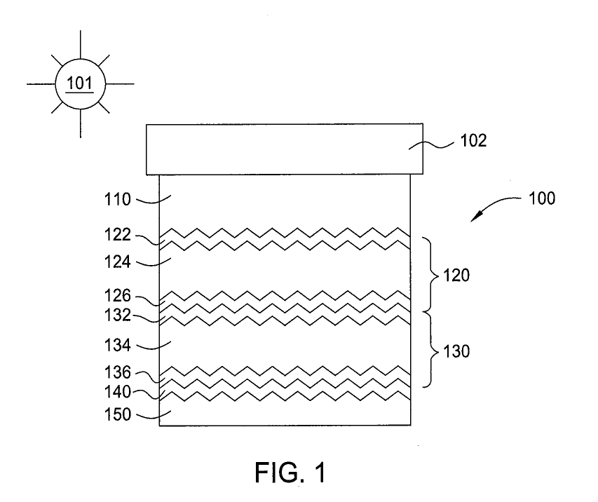

Embodiments of the present invention include methods for forming a doped amorphous silicon oxide layer that may be used in thin film solar cell devices and the thin film solar cell structure formed by the same. The doped amorphous silicon oxide layer may have p-type dopants or n-type dopants doped therein as needed. FIG. 1 is a schematic diagram of certain embodiments of a multi-junction solar cell 100 oriented toward the light or solar radiation 101. Solar cell 100 comprises a substrate 102, such as a glass substrate, polymer substrate, metal substrate, or other suitable substrate, with thin films formed thereover. The solar cell 100 further comprises a first transparent conducting oxide (TCO) layer 110 formed over the substrate 102, a first p-i-n junction 120 formed over the first TCO layer 110, a second p-i-n junction 130 formed over the first p-i-n junction 120, a second TCO layer 140 formed over the second p-i-n junction 130, and a metal back layer 150 formed over the second TCO layer 140. To improve light absorption by enhancing light trapping, the substrate and/or one or more of thin films formed thereover may be optionally textured by wet, plasma, ion, and/or mechanical processes. For example, in the embodiment shown in FIG. 1, the first TCO layer 110 is textured and the subsequent thin films deposited thereover will generally follow the topography of the surface below it.

The first TCO layer 110 and the second TCO layer 140 may each comprise tin oxide, tin oxide with dopants, zinc oxide, indium tin oxide, cadmium stannate, combinations thereof, or other suitable materials. It is understood that the TCO materials may also include additional dopants and components. For example, zinc oxide may further include dopants, such as aluminum, gallium, boron, and other suitable dopants. Zinc oxide preferably comprises 5 atomic % or less of dopants, and more preferably comprises 2.5 atomic % or less aluminum. Tin oxide may further include dopants, such as fluorine, carbon, boron, and other suitable dopants. In an exemplary embodiment depicted herein, The first TCO layer 110 is a tin oxide layer with fluorine dopants (SnO₂:F) doped therein. In certain instances, the substrate 102 may be provided by glass manufacturers with the first TCO layer 110 already provided.

The first p-i-n junction 120 may comprise a p-type amorphous silicon containing layer 122, an intrinsic type amorphous silicon containing layer 124 formed over the p-type amorphous silicon containing layer 122, and an n-type microcrystalline silicon containing layer 126 formed over the intrinsic type amorphous silicon containing layer 124. In certain embodiments, the p-type amorphous silicon containing layer 122 may be formed to a thickness between about 60 Å and about 300 Å. In certain embodiments, the intrinsic type amorphous silicon containing layer 124 may be formed to a thickness between about 1,500 Å and about 3,500 Å. In certain embodiments, the n-type microcrystalline silicon containing layer 126 may be formed to a thickness between about 100 Å and about 400 Å.

The second p-i-n junction 130 may comprise a p-type microcrystalline silicon containing layer 132, an intrinsic type microcrystalline silicon containing layer 134 formed over the p-type microcrystalline silicon containing layer 132, and an n-type amorphous silicon containing layer 136 formed over the intrinsic type microcrystalline silicon containing layer 134. In certain embodiments, the p-type microcrystalline silicon containing layer 132 may be formed to a thickness between about 100 Å and about 400 Å. In certain embodiments, the intrinsic type microcrystalline silicon containing layer 134 may be formed to a thickness between about 10,000 Å and about 30,000 Å. In certain embodiments, the n-type amorphous silicon containing layer 136 may be formed to a thickness between about 100 Å and about 500 Å.

The metal back layer 150 may include, but not limited to a material selected from the group consisting of Al, Ag, Ti, Cr, Au, Cu, Pt, alloys thereof, or combinations thereof. Other processes may be performed to form the solar cell 100, such a laser scribing processes. Other films, materials, substrates, and/or packaging may be provided over metal back layer 150 to complete the solar cell. The solar cells may be interconnected to form modules, which in turn can be connected to form arrays.

Solar radiation 101 is absorbed by the intrinsic layers of the p-i-n junctions 120, 130 and is converted to electron-holes pairs. The electric field created between the p-type silicon containing layer and the n-type silicon containing layer that stretches across the intrinsic silicon containing layer causes electrons to flow toward the n-type silicon containing layers and holes to flow toward the p-type silicon containing layers creating current. The first p-i-n junction 120 comprises an intrinsic type amorphous silicon containing layer 124 and the second p-i-n junction 130 comprises an intrinsic type microcrystalline silicon containing layer 134 because amorphous silicon and microcrystalline silicon absorb different wavelengths of solar radiation 101. Therefore, the solar cell 100 is more efficient since it captures a larger portion of the solar radiation spectrum. The intrinsic silicon containing layer of amorphous silicon and the intrinsic silicon containing layer of microcrystalline silicon containing layer are stacked in such a way that solar radiation 101 first strikes the intrinsic type amorphous silicon containing layer 124 and then strikes the intrinsic type microcrystalline silicon containing layer 134 since amorphous silicon containing has a larger bandgap than microcrystalline silicon containing layer. Solar radiation not absorbed by the first p-i-n junction 120 continues on to the second p-i-n junction 130. It was surprising to find that the thicknesses disclosed herein of the p-i-n layers of the first p-i-n junction 120 and the second p-i-n junction 130 provided for a solar cell with improved efficiency and with a reduced cost of producing the same. Not wishing to be bound by theory unless explicitly recited in the claims, it is believed that on one hand a thicker intrinsic silicon containing layer 124, 134 is beneficial to absorb a greater amount of the solar radiation spectrum and that on the other hand if the intrinsic silicon containing layer 124, 134 and/or the p-i-n junctions 120, 130 are too thick the flow of electrons therethrough would be hampered.

In one aspect, the solar cell 100 does not need to utilize a metal tunnel layer between the first p-i-n junction 120 and the second p-i-n junction 130. The n-type microcrystalline silicon layer 126 of the first p-i-n junction 120 and the p-type microcrystalline silicon layer 132 has sufficient conductivity to provide a tunnel junction to allow electrons to flow from the first p-i-n junction 120 to the second p-i-n junction 130.

In one aspect, it is believed that the n-type amorphous silicon containing layer 136 of the second p-i-n junction 130 provides increased cell efficiency since it is more resistant to attack from oxygen, such as the oxygen in air. Oxygen may attack the silicon films and thus forming impurities which lower the capability of the films to participate in electron/hole transport therethrough. It is also believed that the lower electrical resistivity of an amorphous silicon containing layer versus a crystalline silicon layer the formed solar cell structure/device will have improved electrical properties due to the reduced affect of unwanted shunt paths on the power generation in the formed second p-i-n junction 130. Shunt paths, which generally extend vertically through the formed p-i-n layers, degrade the solar cells performance by shorting out local lateral regions of the formed solar cell device. Therefore, since the lateral resistance of the n-type amorphous silicon containing layer (i.e., perpendicular to the vertical direction) is much higher than a crystalline layer, the lower the affect that a shunt type defect will have on the rest of the formed solar cell. The reduction in the affect of shunt type defects will improve the solar cell's device performance.

In the embodiment wherein a single junction solar cell structure is desired rather than tandem junctions or multiple junctions, the second p-i-n junction 130 may be eliminated, with the first p-i-n junction 120 only remaining in the solar cell 100.

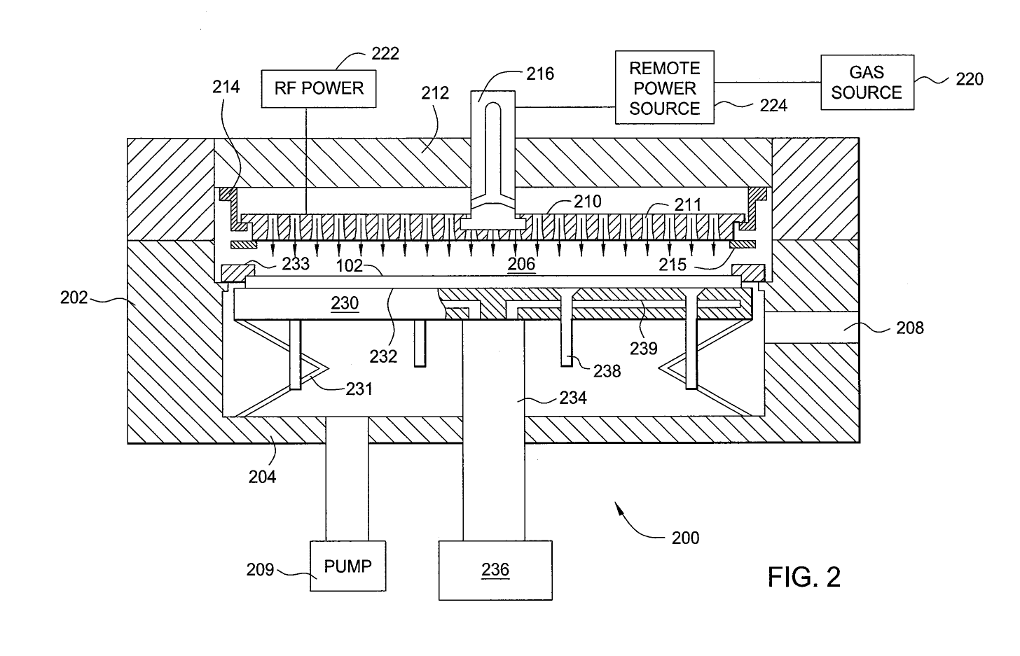

FIG. 2 is a schematic cross-section view of one embodiment of a plasma enhanced chemical vapor deposition (PECVD) chamber 200 in which one or more films of a solar cell, such as the solar cell 100 of FIG. 1 may be deposited. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 200 generally includes walls 202, a bottom 204, and a showerhead 210, and substrate support 230 which define a process volume 206. The process volume is accessed through a valve 208 such that the substrate, such as substrate 102, may be transferred in and out of the chamber 200. The substrate support 230 includes a substrate receiving surface 232 for supporting a substrate 102 and stem 234 coupled to a lift system 236 to raise and lower the substrate support 230. A shadow from 233 may be optionally placed over periphery of the substrate 102. Lift pins 238 are moveably disposed through the substrate support 230 to move a substrate to and from the substrate receiving surface 232. The substrate support 230 may also include heating and/or cooling elements 239 to maintain the substrate support 230 at a desired temperature. The substrate support 230 may also include grounding straps 231 to provide RF grounding at the periphery of the substrate support 230. Examples of grounding straps are disclosed in U.S. Pat. No. 6,024,044 issued on Feb. 15, 2000 to Law et al. and U.S. patent application Ser. No. 11/613,934 filed on Dec. 20, 2006 to Park et al., which are both incorporated by reference in their entirety to the extent not inconsistent with the present disclosure.

The showerhead 210 is coupled to a backing plate 212 at its periphery by a suspension 214. The showerhead 210 may also be coupled to the backing plate by one or more center supports 216 to help prevent sag and/or control the straightness/curvature of the showerhead 210. A gas source 220 is coupled to the backing plate 212 to provide gas through the backing plate 212 and through the showerhead 210 to the substrate receiving surface 232. A vacuum pump 209 is coupled to the chamber 200 to control the process volume 206 at a desired pressure. An RF power source 222 is coupled to the backing plate 212 and/or to the showerhead 210 to provide a RF power to the showerhead 210 so that an electric field is created between the showerhead and the substrate support so that a plasma may be generated from the gases between the showerhead 210 and the substrate support 230. Various RF frequencies may be used, such as a frequency between about 0.3 MHz and about 200 MHz. In one embodiment the RF power source is provided at a frequency of 13.56 MHz. Examples of showerheads are disclosed in U.S. Pat. No. 6,477,980 issued on Nov. 12, 2002 to White et al., U.S. Publication 20050251990 published on Nov. 17, 2006 to Choi et al., and U.S. Publication 2006/0060138 published on Mar. 23, 2006 to Keller et al, which are all incorporated by reference in their entirety to the extent not inconsistent with the present disclosure.

A remote plasma source 224, such as an inductively coupled remote plasma source, may also be coupled between the gas source and the backing plate. Between processing substrates, a cleaning gas may be provided to the remote plasma source 224 so that a remote plasma is generated and provided to clean chamber components. The cleaning gas may be further excited by the RF power source 222 provided to the showerhead. Suitable cleaning gases include but are not limited to NF₃, F₂, and SF₆. Examples of remote plasma sources are disclosed in U.S. Pat. No. 5,788,778 issued Aug. 4, 1998 to Shang et al, which is incorporated by reference to the extent not inconsistent with the present disclosure.

The deposition methods for one or more silicon layers, such as one or more of the silicon layers of solar cell 100 of FIG. 1, may include the following deposition parameters in the process chamber of FIG. 2 or other suitable chamber. A substrate having a surface area of 10,000 cm² or more, for example about 40,000 cm² or more, such as 55,000 cm² or more is provided to the chamber. It is understood that after processing the substrate may be cut to form smaller solar cells.

In one embodiment, the heating and/or cooling elements 239 may be set to provide a substrate support temperature during deposition of about 400 degrees Celsius or less, such as between about 100 degrees Celsius and about 400 degrees Celsius, for example between about 150 degrees Celsius and about 300 degrees Celsius, such as about 200 degrees Celsius.

The spacing during deposition between the top surface of a substrate disposed on the substrate receiving surface 232 and the showerhead 210 may be between 400 mil and about 1,200 mil, for example between 400 mil and about 800 mil.

For deposition of silicon films, a silicon-based gas and a hydrogen-based gas are provided. Suitable silicon based gases include, but are not limited to silane (SiH₄), disilane (Si₂H₆), silicon tetrafluoride (SiF₄), silicon tetrachloride (SiCl₄), dichlorosilane (SiH₂Cl₂), and combinations thereof. Suitable hydrogen-based gases include, but are not limited to hydrogen gas (H₂). The p-type dopants of the p-type silicon containing layers may each comprise a group III element, such as boron or aluminum. Boron is used as the p-type dopant. Examples of boron-containing sources include trimethylboron (TMB (or B(CH₃)₃)), diborane (B₂H₆), BF₃, B(C₂H₅)₃, and similar compounds. In one embodiment, TMB is used as the p-type dopant. The n-type dopants of the n-type silicon containing layer may each comprise a group V element, such as phosphorus, arsenic, or antimony. Phosphorus is used as the n-type dopant. Examples of phosphorus-containing sources include phosphine and similar compounds. The dopants are typically provided with a carrier gas, such as hydrogen, argon, helium, and other suitable compounds. In the process regimes disclosed herein, a total flow rate of hydrogen gas is provided. Therefore, if a hydrogen gas is provided as the carrier gas, such as for the dopant, the carrier gas flow rate should be subtracted from the total flow rate of hydrogen to determine how much additional hydrogen gas should be provided to the chamber.

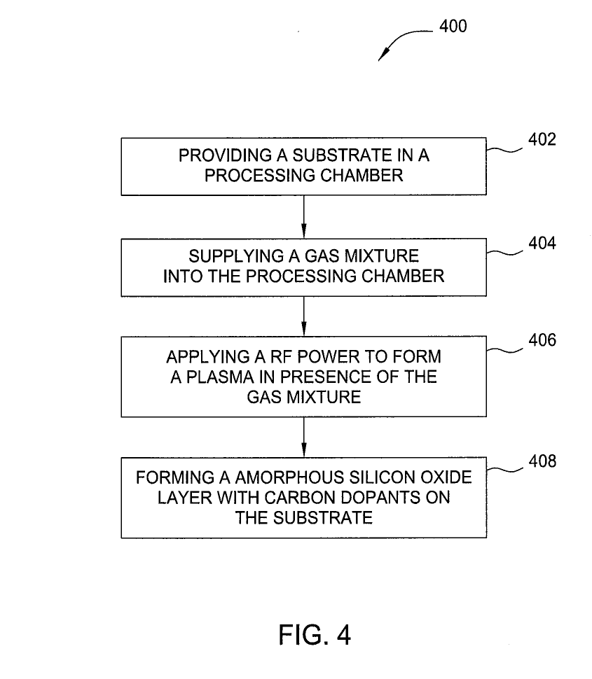

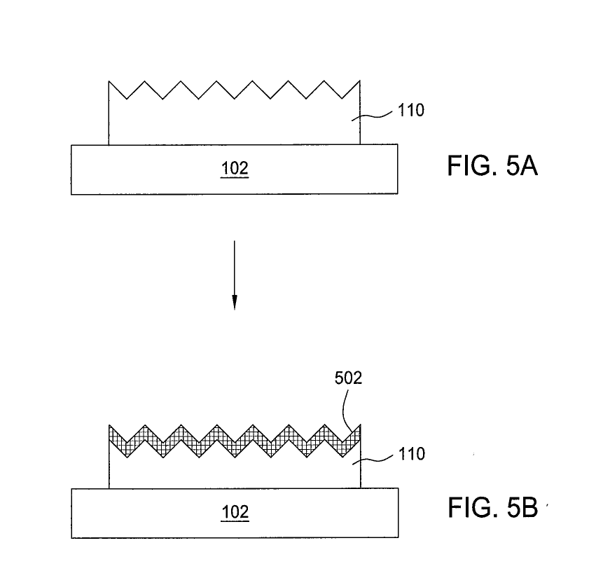

Detail process for forming the p-type amorphous silicon containing layer, such as the silicon layer 122 of FIG. 1, will be further discussed above with referenced to FIGS. 4-5.

Certain embodiments of depositing an intrinsic type amorphous silicon layer, such as the silicon layer 124 of FIG. 1, comprises providing a gas mixture of hydrogen gas to silane gas in a ratio of about 20:1 or less. Silane gas may be provided at a flow rate between about 0.5 sccm/L and about 7 sccm/L. Hydrogen gas may be provided at a flow rate between about 5 sccm/L and 60 sccm/L. An RF power between 15 milliWatts/cm² and about 250 milliWatts/cm² may be provided to the showerhead. The pressure of the chamber may be maintained between about 0.1 Torr and 20 Torr, for example between about 0.5 Torr and about 5 Torr. The deposition rate of the intrinsic type amorphous silicon layer may be about 100 Å/min or more. In an exemplary embodiment, the intrinsic type amorphous silicon layer is deposited at a hydrogen to silane ratio at about 12.5:1.

Certain embodiments of depositing a n-type microcrystalline silicon layer, such as the silicon layer 126 of FIG. 1, may comprise providing a gas mixture of hydrogen gas to silane gas in a ratio of about 100:1 or more. Silane gas may be provided at a flow rate between about 0.1 sccm/L and about 0.8 sccm/L, such as about 0.35 sccm/L. Hydrogen gas may be provided at a flow rate between about 30 sccm/L and about 250 sccm/L, such as about 71.43 sccm/L. Phosphine may be provided at a flow rate between about 0.0005 sccm/L and about 0.006 sccm/L. In other words, if phosphine is provided in a 0.5% molar or volume concentration in a carrier gas, then the dopant/carrier gas may be provided at a flow rate between about 0.1 sccm/L and about 1.2 sccm/L. An RF power between about 100 milliWatts/cm² and about 900 milliWatts/cm² may be provided to the showerhead. The pressure of the chamber may be maintained between about 1 Torr and about 100 Torr, for example between about 3 Torr and about 20 Torr, such as between 4 Torr and about 12 Torr. The deposition rate of the n-type microcrystalline silicon layer may be about 50 Å/min or more. The n-type microcrystalline silicon layer has a crystalline fraction between about 20 percent and about 80 percent, such as between 50 percent and about 70 percent. In the embodiment wherein phosphine is used to provide phosphorous dopants in the n-type microcrystalline silicon layer, the phosphorous dopant concentration is maintained at between about 1×10¹⁸ atoms/cm² and about 1×10²⁰ atoms/cm².

Certain embodiments of depositing a p-type microcrystalline silicon layer, such as silicon layer 132 of FIG. 1, comprises providing a gas mixture of hydrogen gas to silane gas in a ratio of about 200:1 or greater. Silane gas may be provided at a flow rate between about 0.1 sccm/L and about 0.8 sccm/L. Hydrogen gas may be provided at a flow rate between about 60 sccm/L and about 500 sccm/L. Trimethylboron may be provided at a flow rate between about 0.0002 sccm/L and about 0.0016 sccm/L. In other words, if trimethylboron is provided in a 0.5% molar or volume concentration in a carrier gas, then the dopant/carrier gas mixture may be provided at a flow rate between about 0.04 sccm/L and about 0.32 sccm/L. An RF power between about 50 milliWatts/cm² and about 700 milliWatts/cm² may be provided to the showerhead. The pressure of the chamber may be maintained between about 1 Torr and about 100 Torr, for example between about 3 Torr and about 20 Torr, such as between 4 Torr and about 12 Torr. The deposition rate of the p-type microcrystalline silicon layer may be about 10 Å/min or more. The p-type microcrystalline silicon contact layer has a crystalline fraction between about 20 percent and about 80 percent, for example between 50 percent and about 70 percent. In the embodiment wherein trimethylboron is used to provide boron dopants in the p-type microcrystalline silicon layer, the boron dopant concentration is maintained at between about 1×10¹⁸ atoms/cm² and about 1×10²⁰ atoms /cm².

Certain embodiments of depositing an intrinsic type microcrystalline silicon layer, such as silicon layer 134 of FIG. 1, may comprise providing a gas mixture of silane gas to hydrogen gas in a ratio between 1:20 and 1:200. Silane gas may be provided at a flow rate between about 0.5 sccm/L and about 5 sccm/L. Hydrogen gas may be provided at a flow rate between about 40 sccm/L and about 400 sccm/L. In certain embodiments, the silane flow rate may be ramped up from a first flow rate to a second flow rate during deposition. In certain embodiments, the hydrogen flow rate may be ramped down from a first flow rate to a second flow rate during deposition. An RF power between about 300 milliWatts/cm² or greater, such as about 600 milliWatts/cm² or greater, may be provided to the showerhead. In certain embodiments, the power density may be ramped down from a first power density to a second power density during deposition. The pressure of the chamber is maintained between about 1 Torr and about 100 Torr, such as between about 3 Torr and about 20 Torr, for example between about 4 Torr and about 12 Torr. The deposition rate of the intrinsic type microcrystalline silicon layer may be about 200 Å/min or more, preferably 500 Å/min. Methods and apparatus for deposited microcrystalline intrinsic layer are disclosed in U.S. patent application Ser. No. 11/426,127 filed Jun. 23, 2006, entitled “Methods and Apparatus for Depositing a Microcrystalline Silicon Film for Photovoltaic Device,” which is incorporated by reference in its entirety to the extent not inconsistent with the present disclosure. The microcrystalline silicon intrinsic layer has a crystalline fraction between about 20 percent and about 80 percent, preferably between 55 percent and about 75 percent. It was surprising to find that a microcrystalline silicon intrinsic layer having a crystalline fraction of about 70% or below provided an increase in open circuit voltage and leads to higher cell efficiency.

Certain embodiments of a method depositing a n-type amorphous silicon layer, such as the silicon layer 136 of FIG. 1, may comprise depositing an optional first n-type amorphous silicon layer at a first silane flow rate and depositing a second n-type amorphous silicon layer over the first optional n-type amorphous silicon layer at a second silane flow rate lower than the first silane flow rate. The first optional n-type amorphous silicon layer may comprise providing a gas mixture of hydrogen gas to silane gas in a ratio of about 20:1 or less, such as about 5:5:1. Silane gas may be provided at a flow rate between about 1 sccm/L and about 10 sccm/L, such as about 5.5 sccm/L. Hydrogen gas may be provided at a flow rate between about 4 sccm/L and about 40 sccm/L, such as about 27 sccm/L. Phosphine may be provided at a flow rate between about 0.0005 sccm/L and about 0.0015 sccm/L, such as about 0.0095 sccm/L. In other words, if phosphine is provided in a 0.5% molar or volume concentration in a carrier gas, then the dopant/carrier gas mixture may be provided at a flow rate between about 0.1 sccm/L and about 3 sccm/L, such as about 1.9 sccm/L. An RF power between 25 milliWatts/cm² and about 250 milliWatts/cm², such as about 80 milliWatts/cm², may be provided to the showerhead. The pressure of the chamber may be maintained between about 0.1 Torr and about 20 Torr, such as between about 0.5 Torr and about 4 Torr, such as about 1.5 Torr. The deposition rate of the first n-type amorphous silicon layer may be about 200 Å/min or more, such as about 561 Å/min. In the embodiment wherein phosphine is used to provide phosphorous dopants in the n-type amorphous silicon layer, the phosphorous dopants concentration is maintained at between about 1×10¹⁸ atoms/cm² and about 1×10²⁰ atoms/cm².

It is noted that prior to each deposition of the layers, including n-type, intrinsic type and p-type silicon containing layers, an optional hydrogen or argon plasma gas treatment process may be performed. The hydrogen treatment process may be performed to treat the underlying layer to suppress surface contamination. Furthermore the plasma treatment process can also improve electrical properties at the interface since the surface defects may be removed or eliminated during the treatment process. In one embodiment, the plasma treatment process may be performed by supplying a hydrogen gas or argon gas into the processing chamber. The gas flow for supplying the hydrogen gas or the argon gas is between about 10 sccm/L and about 45 sccm/L, such as between about 15 sccm/L and about 40 sccm/L, for example about 20 sccm/L and about 36 sccm/L. In one example, the hydrogen gas may be supplied at about 21.42 sccm/L or the argon gas may be supplied at about 35.7 sccm/L. The RF power supplied to do the treatment process may be controlled at between about 25 milliWatts/cm² and about 250 milliWatts/cm², such as about 60 milliWatts/cm², may be provided to the showerhead 10 milliWatts/cm² and about 250 milliWatts/cm², such as about 80 milliWatts/cm² for hydrogen treatment and about 25 milliWatts/cm² for argon treatment.

In one embodiment, an argon treatment process is performed prior to deposition of a p-type amorphous silicon layer. In one embodiment, a hydrogen treatment process may be performed prior to deposition of each of the intrinsic type amorphous silicon layer, n-type microcrystalline silicon layer, p-type microcrystalline silicon layer, and intrinsic type microcrystalline silicon layer and other layers when beneficial.

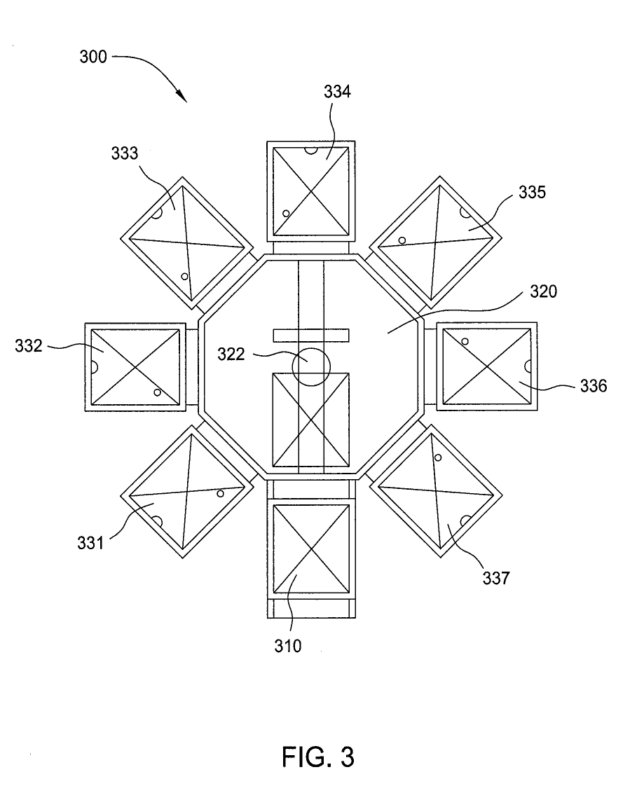

FIG. 3 is a top schematic view of one embodiment of a process system 300 having a plurality of process chambers 331-337, such as PECVD chambers chamber 200 of FIG. 2 or other suitable chambers capable of depositing silicon containing films. The process system 300 includes a transfer chamber 320 coupled to a load lock chamber 310 and the process chambers 331-537. The load lock chamber 310 allows substrates to be transferred between the ambient environment outside the system and vacuum environment within the transfer chamber 320 and process chambers 331-337. The load lock chamber 310 includes one or more evacuatable regions holding one or more substrate. The evacuatable regions are pumped down during input of substrates into the system 300 and are vented during output of the substrates from the system 300. The transfer chamber 320 has at least one vacuum robot 322 disposed therein that is adapted to transfer substrates between the load lock chamber 310 and the process chambers 331-337. Seven process chambers are shown in FIG. 3; however, the system may have any suitable number of process chambers.

In certain embodiments of the invention, one system 300 is configured to deposit the first p-i-n junction comprising an intrinsic type amorphous silicon layer(s) of a multi-junction solar cell, such as the first p-i-n junction 120. One of the process chambers 331-337 is configured to deposit the p-type silicon containing layer(s) of the first p-i-n junction while the remaining process chambers 331-337 are each configured to deposit both the intrinsic type amorphous silicon containing layer(s) and the n-type silicon containing layer(s). The intrinsic type amorphous silicon containing layer(s) and the n-type silicon containing layer(s) of the first p-i-n junction may be deposited in the same chamber without any passivation process in between the deposition steps. Thus, a substrate enters the system through the load lock chamber 310, is transferred by the vacuum robot into the dedicated process chamber configured to deposit the p-type silicon layer(s), is transferred by the vacuum robot into one of the remaining process chamber configured to deposited both the intrinsic type silicon layer(s) and the n-type silicon layer(s), and is transferred by the vacuum robot back to the load lock chamber 310. In certain embodiments, the time to process a substrate with the process chamber to form the p-type silicon layer(s) is approximately 4 or more times faster, such as about 6 or more times faster, than the time to form the intrinsic type amorphous silicon layer(s) and the n-type silicon layer(s) in a single chamber. Therefore, in certain embodiments of the system to deposit the first p-i-n junction, the ratio of p-chambers to i/n-chambers is 1:4 or more, such as 1:6 or more. The throughput of the system including the time to provide plasma cleaning of the process chambers may be about 10 substrates/hr or more, for example about 20 substrates/hr or more.

FIG. 4 depicts a process flow diagram for forming a doped amorphous silicon containing layer, such as the p-type doped amorphous silicon layer 122, that may be utilized in thin-film solar cell devices according to one embodiment of the invention. The process 400 starts at step 402 by transferring a substrate, such as the substrate 102 into a processing chamber. The processing chamber may be any suitable deposition chamber, such as a chemical vapor deposition (CVD) chamber 200 depicted in FIG. 2. In one embodiment, the substrate may be a thin sheet of metal, plastic, organic material, silicon, glass, quartz, polymer, or other suitable material. The substrate 102 may have a transparent conductive layer or a transparent conductive oxide (TCO) layer, such as the TCO layer 110 depicted in FIG. 1, formed thereon prior to transferring into the processing chamber, as depicted in FIG. 5A.

At step 404, a gas mixture is supplied into the processing chamber to form a p-type amorphous silicon containing layer 502 on the substrate, as shown in FIG. 5B. The gas mixture includes at least a silicon containing gas, a hydrogen containing gas, a p-type dopant containing gas and an oxygen containing gas. The oxygen containing gas supplied in the gas mixture is configured to provide an oxygen source to the gas mixture so as to form the resultant layer as a silicon oxide containing gas, such as a p-type doped silicon oxide layer. Suitable examples of the silicon containing gas include silane (SiH₄), disilane (Si₂H₆), silicon tetrafluoride (SiF₄), silicon tetrachloride (SiCI₄), dichlorosilane (SiH₂Cl₂), and combinations thereof. Suitable hydrogen-based gas includes, but is not limited to, hydrogen gas (H₂). Suitable examples of the p-type dopant containing gas include trimethylboron (TMB (or B(CH₃)₃)), diborane (B₂H₆), BF₃, B(C₂H₅)₃, and similar compounds. Suitable examples of the oxygen containing gas include CO₂, CO, N₂O, NO₂, O₂, O₃, H₂O and the like. In one embodiment wherein the p-type amorphous silicon containing layer 502 is configured to be a carbon containing (e.g., carbon doped) p-type amorphous silicon containing layer, the oxygen containing gas supplied in the gas mixture may be configured to be a carbon and oxygen containing gas, such as CO₂, CO or the like. In an exemplary embodiment depicted herein, TMB is used as the p-type dopant containing gas, silane is used as the silicon containing gas and the CO₂ gas is used as the oxygen containing gas so as to form a carbon doped p-type amorphous silicon oxide layer on the substrate 502 as the p-type layer for thin film solar cell devices.

In one embodiment, the hydrogen gas and the silane gas supplied in the gas mixture has a hydrogen gas to silane gas supplied in a ratio (H₂/SiH₄) of between about 5:1 and about 50:1, such as less than about 30:1, for example between about 15:1 and about 5:1. Silane gas may be provided at a flow rate between about 1 sccm/L and about 10 sccm/L. Hydrogen gas may be provided at a flow rate between about 5 sccm/L and 60 sccm/L. Trimethylboron (TMB) may be provided at a flow rate between about 0.005 sccm/L and about 0.05 sccm/L. In other words, if trimethylboron is provided in a 0.5% molar or volume concentration in a carrier gas, then the dopant/carrier gas mixture may be provided at a flow rate between about 1 sccm/L and about 10 sccm/L. In one embodiment, the ratio of oxygen containing gas flow rate to silane flow rate is between about 0.5 and about 3, such as between about 1.5 and about 2.5, for example about 2. As discussed above, in the embodiment wherein the p-type amorphous silicon containing layer 502 is configured to be a carbon doped amorphous silicon oxide layer, a CO₂ gas may be utilized to both provide oxygen element and carbon element in the gas mixture so as to form the carbon doped amorphous silicon oxide layer as needed. The flow of CO₂ gas (G_{CO2}) supplied in the gas mixture may be controlled to a predetermined ratio to the total combined gas flow of H₂ and SiH₄ gas flow (T_{C}) supplied in the gas mixture. In one embodiment, the ratio of the CO₂ gas flow (G_{Ar}) to the total gas flow (T_{C}) of H₂ and SiH₄ supplied in the gas mixture is controlled to between about 10 percent and about 50 percent by volume (e.g., G_{CO}/T_{C} value between 3 percent and about 35 percent by volume). For example, in an embodiment wherein the CO₂ gas flow is supplied at about 225 sccm, the total combined gas flow of H₂ and SiH₄ may be between about 3000 sccm and about 4000 sccm. In one embodiment, the ratio of CO₂ gas flow (G_{CO2}) to the total gas flow (T_{C}) of H₂ and SiH₄ (e.g., G_{CO2}/T_{C} value) is controlled between about 3 percent and about 35 percent by volume, such as between about 10 percent and about 20 percent by volume, for example about 15 percent by volume. Furthermore, the ratio of CO₂ gas to silane gas supplied in the gas mixture may be controlled at between about 0.5 and about 3. The ratio of CO₂ gas supplied in the gas mixture may be varied to adjust the amount of carbon in the deposited film.

In yet another embodiment, the p-type dopant containing gas, such as the TMB gas, supplied in the gas mixture may be controlled to a ratio of p-type dopant containing gas to the CO₂ gas (TMB/CO₂) at between about 50 percent and about 200 percent.

At step 406, a RF power is applied to form a plasma in the presence of the gas mixture. A RF source power may be applied to maintain the plasma during deposition. In one embodiment, the RF source power density may be supplied between about 30 mWatt/cm² and about 100 mWatt/cm². A RF bias power may be applied to maintain the plasma during deposition. In one embodiment, the RF bias power density may be supplied between about 30 mWatt/cm² and about 100 mWatt/cm². The RF source and bias power are provided between about 100 kHz and about 100 MHz, such as about 350 kHz or about 13.56 MHz. The process pressure is maintained at between about 0.5 Torr and about 10 Torr, such as between about 1 Torr and about 3 Torr, such as about 1.5 Torr and about 2.5 Torr. The spacing of the substrate to the gas distribution plate assembly may be controlled in accordance with the substrate dimension. In one embodiment, the processing spacing for a substrate greater than 1 square meters is controlled between about 400 mils and about 1200 mils, for example, between about 400 mils and about 850 mils, such as 650 mils. The substrate temperature may be controlled at between about 150 degrees Celsius and about 500 degrees Celsius, such as about 220 degrees Celsius.

At step 408, after the RF power is applied in the gas mixture, the carbon doped p-type amorphous silicon oxide layer 502 may be formed on the substrate. The carbon doped p-type amorphous silicon oxide layer 502 is configured to improve the window properties (e.g. to lower absorption of solar radiation) of carbon doped p-type amorphous silicon oxide layer, as compared to the conventional p-type amorphous silicon layer. It is believed that the amorphous silicon oxide layer is more transparent than the conventional amorphous silicon layer utilized to form the p-type layer, thereby allowing more light to transmit therethrough to the intrinsic type silicon containing layer 124 subsequently formed thereon. Thus, an increased amount of solar radiation may be absorbed through the intrinsic layers and thus cell efficiency is improved. Furthermore, a higher optical band gap, lower refraction index and lower defect density may also be obtained

In the embodiment wherein trimethylboron is used to provide boron dopants in the carbon p-type amorphous silicon oxide layer 122, the boron dopant concentration is maintained at between about 1×10¹⁸ atoms/cm² and about 1×10²⁰ atoms/cm². In the embodiment wherein the CO₂ gas is used to provide to form the carbon doped p-type silicon oxide layer, the carbon dopant concentration is controlled between about 0.1 atomic percent and about 10 atomic percent of the layer, such as between about 0.5 atomic percent and about 5 atomic percent of the layer, for example about 1 atomic percent of the layer, or maintained between about 1×10¹⁸ atoms/cm³ and about 1×10²⁰ atoms/cm³. The resultant carbon doped p-type amorphous silicon oxide layer may have a formula of Si_{1-x-y}OₓC_{y}, wherein x is at a range between about 0.05 and 0.5 and y is at a range between about 0.01 and about 0.7. As the carbon dopants doped in the p-type amorphous silicon oxide layer is believed to improve the conductivity of the film layer, the resultant carbon doped p-type amorphous silicon oxide layer may be controlled to have a conductivity between about 1×E⁻⁶ and about 1×E⁻⁹. The conductivity of the carbon dopants doped in the p-type amorphous silicon oxide layer may be improved about 30 percent, as compared to the conventional p-type silicon containing layer. Furthermore, the carbon dopants doped in the p-type amorphous silicon oxide layer is believed to have a high response rate to blue light, such as about 10 percent and about 30 higher than conventional practice.

Thus, the methods described herein advantageously improve the film transparency, conductivity, and stability of electric devices by controlling the film properties of the p-type doped silicon containing layer, such as a carbon doped p-type silicon oxide layer, formed in the solar cell devices.

While the foregoing is directed to embodiments of the present invention, other and further embodiments of the invention may be devised without departing from the basic scope thereof, and the scope thereof is determined by the claims that follow.

1. A method for forming a doped p-type amorphous silicon containing layer on a substrate comprising:
providing a substrate in a processing chamber;
supplying a gas mixture having a hydrogen-based gas, a silicon-based gas and a carbon and oxygen containing gas into the processing chamber, the gas mixture having a volumetric flow ratio of the hydrogen-based gas to the silicon-based gas between about 5 and about 15, wherein a volumetric flow ratio of the carbon and oxygen containing gas to the total combined flow of hydrogen-based gas and the silicon-based gas is between about 10 percent and about 50 percent; and
maintaining a process pressure of the gas mixture within the processing chamber at between about 1 Torr and about 10 Torr while forming a doped p-type amorphous silicon containing layer.

2. The method of claim 1, wherein the doped p-type amorphous silicon containing layer is a carbon doped amorphous silicon oxide layer.

3. The method of claim 1, wherein supplying the gas mixture further comprises:
supplying a p-type dopant containing gas in the gas mixture.

4. The method of claim 3, wherein the p-type dopant containing gas is selected from a group consisting of trimethylboron (TMB (or B(CH₃)₃)), diborane (B₂H₆), BF₃ and B(C₂H₅)₃.

5. The method of claim 2, wherein the carbon doped amorphous silicon oxide layer has a carbon concentration controlled between about 0.1 atomic percent and about 10 atomic percent.

6. The method of claim 3, wherein supplying the p-type dopant containing gas further comprises:
supplying the p-type dopant containing gas in the gas mixture having a ratio of p-type dopant containing gas to the carbon and oxygen containing gas at between about 50 percent to about 200 percent.

7. The method of claim 1, wherein the carbon and oxygen containing gas is CO₂.

8. The method of claim 1, wherein the silicon containing gas is SiH₄ and the hydrogen containing gas is H₂.

9. The method of claim 1, further comprising:
applying a RF power between about 30 mWatt/cm² and about 100 mWatt/cm² to maintain a plasma formed from the gas mixture.

10. The method of claim 1, wherein the substrate includes a fluorine doped tin oxide layer disposed thereon prior to forming the doped p-type amorphous silicon containing layer.

11. A method for forming a doped p-type amorphous silicon containing layer on a substrate for solar cell devices comprising:
providing a substrate having a fluorine doped tin oxide layer disposed thereon in a processing chamber;
supplying a gas mixture having a H₂ gas, a SiH₄ gas and an CO₂ gas into the processing chamber, wherein the H₂ gas to SiH₄ gas having a volumetric flow ratio of between about 5 and about 15, wherein volumetric flow ratio of the CO₂ gas to the total combined flow of H₂ gas and the SiH₄ gas is between about 10 percent and about 50 percent; and
applying a RF power to form a plasma in the presence of the gas mixture to deposit a carbon doped p-type amorphous silicon oxide layer on the substrate, wherein the carbon doped p-type amorphous silicon oxide layer is controlled to have a carbon concentration between about 0.1 atomic percent and about 10 atomic percent.

12. The method of claim 11, further comprising:
maintaining a process pressure of the gas mixture within the processing chamber at between about 1 Torr and about 10 Torr while depositing carbon doped p-type amorphous silicon oxide layer.

13. The method of claim 11, wherein supplying the gas mixture further comprises:
supplying a p-type dopant containing gas in the gas mixture.

14. The method of claim 13, wherein the p-type dopant containing gas is selected from a group consisting of trimethylboron (TMB (or B(CH₃)₃)), diborane (B₂H₆), BF₃ and B(C₂H₅)₃.

15. The method of claim 13, wherein supplying the p-type dopant containing gas further comprises:
supplying the p-type dopant containing gas in the gas mixture having a ratio of p-type dopant containing gas to the CO₂ gas at between about 50 percent to about 200 percent.

16. The method of claim 15, further comprising:
forming an intrinsic type microcrystalline silicon containing layer over the carbon doped p-type amorphous silicon oxide layer.

17. A thin film solar cell structure, comprising:
a first transparent conductive oxide layer disposed on a substrate;
a carbon doped p-type amorphous silicon oxide layer disposed on the first transparent conductive layer, wherein the carbon concentration doped in the carbon doped p-type amorphous silicon oxide layer is between about 0.1 atomic percent and about 10 atomic percent; an intrinsic type silicon containing layer disposed on the carbon doped p-type amorphous silicon oxide layer; and
a n-type silicon containing layer disposed on the carbon doped p-type amorphous silicon oxide layer.

18. The structure of claim 17, wherein the carbon doped p-type amorphous silicon oxide layer is formed by supplying a gas mixture comprising a H₂ gas, SiH₄ gas and a CO₂ gas, wherein a volumetric flow ratio of the CO₂ gas to the total combined flow of H₂ gas and the SiH₄ gas is controlled at between about 1 percent and about 50 percent.

19. The structure of claim 17, wherein the first transparent conductive oxide layer is a fluorine doped tin oxide layer.

20. The structure of claim 17, wherein the intrinsic type silicon containing layer is an intrinsic type microcrystalline silicon layer, intrinsic type amorphous silicon layer or an intrinsic type nanocrystalline silicon layer.
